(19) United States
(12) Patent Application Publication
(10) Pub. No.: US 2009/0314335 A1
(43) Pub. Date: Dec. 24, 2009

(54) INTEGRAL PHOTOVOLTAIC UNIT

(76) Inventor: Meredith McClintock, Redwood City, CA (US)

Correspondence Address: PERKINS COIE LLP, P.O. BOX 1208, SEATTLE, WA, 98111-1208, US

(21) Appl. No.: 12/237,326

(22) Filed: Sep. 24, 2008

Related U.S. Application Data
(60) Provisional application No. 61/074,283, filed on Jun. 20, 2008.

(51) Int. Cl. H01L 31/042

(52) U.S. Cl. 136/251

(57) ABSTRACT

Systems and methods for facilitating setting up a photovoltaic unit are presented. The current invention describes an integral photovoltaic unit and methods to install this unit onto a roof of a building or onto another structural component.

### CLAIM OF PRIORITY

This application claims priority to U.S. Provisional Patent Application No. 61/074,283 entitled “Integral Photovoltaic Unit”, which was filed on Jun. 20, 2008 by Meredith McClintock., the contents of which are expressly incorporated by reference herein.

### BACKGROUND

Solar cell assemblies are arrangements of devices that convert solar energy in the form of photons into electricity by the photovoltaic effect. A solar cell assembly may be a device that is composed of an arrangement of interconnected solar cells. Non-limiting examples of solar cell assemblies are photovoltaic modules (also called solar modules) or photovoltaic laminates. A photovoltaic module is composed of electrically connected solar cells disposed in a frame. The frame of the photovoltaic module may also include a backing to support the solar cells, and the frame and backing are usually made of a metallic material. Photovoltaic laminates are composed of electrically connected solar cells and usually do not possess a frame.

Installation of solar cell assemblies onto a roof or other part of a building can be very time consuming and can require much expertise on wiring and electrical and electronic parts needed to build a fully functioning solar power device.

### SUMMARY

The following examples and aspects thereof are described and illustrated in conjunction with systems, tools, and methods that are meant to be exemplary and illustrative, not limiting in scope. In various examples, one or more of the above-described problems have been reduced or eliminated, while other examples are directed to other improvements.

Systems and methods for facilitating installation of a photovoltaic unit are presented. The current invention describes an integral photovoltaic unit and methods to install this unit onto a roof of a building or onto another structural component.

### BRIEF DESCRIPTION OF THE DRAWINGS

FIG. 1 depicts an example of an integral photovoltaic unit.

FIG. 2 depicts an example of a triangular shaped rail used in a mounting frame.

FIG. 3 depicts an example of a flat end cap used in a mounting frame.

FIGS. 4A and 4B depict examples of a means for mounting a photovoltaic unit onto an exterior structure.

FIG. 5 depicts an example of a flowchart of a method for mounting an integral photovoltaic unit onto an exterior structure.

FIG. 6 depicts an example of a drill jig for positioning the means for fixing an integral photovoltaic unit onto an exterior structure.

FIG. 7 depicts an example of a system for pulling a photovoltaic unit up to an exterior structure.

FIG. 8 depicts an example of a device for securing solar cell assemblies to a mounting frame.

FIG. 9 depicts an example of a flowchart of a method for selecting the optimal photovoltaic system size.

FIG. 10 depicts an example of a sizing chart for selecting the optimal photovoltaic system size.

FIG. 11 depicts an example of a micro-inverter connected with the integral photovoltaic unit.

FIG. 12 depicts an example of integral photovoltaic units marked with color and/or symbol codes to facilitate installation of an arrangement of the units.

### DETAILED DESCRIPTION

In the following description, several specific details are presented to provide a thorough understanding. One skilled in the relevant art will recognize, however, that the concepts and techniques disclosed herein can be practiced without one or more of the specific details, or in combination with other components, etc. In other instances, well-known implementations or operations are not shown or described in detail to avoid obscuring aspects of various examples disclosed herein.

Systems and methods for facilitating setting up a photovoltaic unit are presented. The current invention describes an integral photovoltaic unit and methods to install this unit onto a roof of a building or onto another external structure. For example, the photovoltaic unit may also be placed on the ground outside a building.

In one embodiment, a system is described that is composed of one or more solar cell assemblies attached to a mounting frame. The solar cell assemblies are wired together prior to delivery to the customer and the system is packaged with matching electronics and electrical accessories.

In one embodiment, the integral photovoltaic unit includes at least one micro-inverter. In a non-limiting example, one micro-inverter may be connected with each solar cell assembly, and the micro-inverter may be attached to the back of the solar cell assembly, to a part of the mounting frame of the integral photovoltaic unit, to a cross-support of the mounting frame, or to another part attached to the integral photovoltaic unit. The micro-inverter may be connected with the solar cell assembly prior to the integral photovoltaic unit being delivered to the site where it will be installed, thereby facilitating installation of the integral photovoltaic unit onto an exterior structure.

In one embodiment, the integral photovoltaic units including the micro-inverters may include visual codes, such as colors and/or symbols, for ease of installation when installing a multitude of integral photovoltaic units. For example, an installer mounts the integral photovoltaic units onto an exterior structure by aligning the color and/or symbol on one corner of one integral photovoltaic unit with the matching color and/or symbol on the corner of a second integral photovoltaic unit. This allows the integral photovoltaic units to be easily and correctly connected together. The micro-inverters convert the DC power provided by the solar cell assemblies into AC power. Having micro-inverters connected with the solar cell assemblies may eliminate the need for DC wiring, disconnects, and other electronic components.

In one embodiment, the mounting frame is made of a metallic material and the solar cell assemblies are grounded. In another embodiment, the mounting frame is made of a non-metallic material, such as, in a non-limiting example, fiber glass or carbon fiber. In this embodiment, the solar cell assemblies do not require grounding.

In one embodiment, a drill jig may be used as a template to identify where to attach the integral photovoltaic unit onto the exterior structure. The drill jig can be placed on the exterior structure where the integral photovoltaic unit will be installed. Slots on the plates attached to the frame of the drill jig may then be used to install fixings on specific locations on the exterior structure. These slots are located on the drill jig in such a way that the fixings will be spaced apart such as to allow the brackets on the mounting frame of the integral photovoltaic unit to be aligned with these fixings.

In one embodiment, the drill jig is used in a factory environment for manufactured or modular homes. The integral photovoltaic units can be installed on an exterior structure of a manufactured or modular home, before the home is transported to its destination. The drill jig makes it possible to efficiently and precisely install photovoltaic units on these homes.

In one embodiment, a protective crate may be placed over an integral photovoltaic unit installed on a manufactured or modular home, to protect the integral photovoltaic unit from damage during transportation of the home. The protective crate is shaped to fit over the integral photovoltaic unit and is made of impact-resistant material. In one embodiment, the material may be wood.

In one embodiment, the mounting frame is composed of two triangular shaped rails attached to flat end caps to form a frame, whereby the two triangular shaped rails are substantially parallel to each other. The mounting frame may have brackets attached to it for fixing the integral photovoltaic unit to an exterior structure.

In one embodiment, the solar cell assemblies of the integral photovoltaic unit are photovoltaic laminates. This reduces material costs and weight, as the photovoltaic laminates do not require a frame. A single photovoltaic laminate may be employed, which reduces the required amount of wiring.

In one embodiment, adjacent solar cell assemblies may be fixed onto a mounting frame by one or more clips that are screwed into a cross support of the mounting frame. Bolts may be used to screw down the clips, and the bolts may be screwed into holes in the cross support, without the need to access the other side of the mounting frame.

In one embodiment, a sizing chart may be used to evaluate the optimal system size for a given customer, based on the customer's location and desired reduction of their electricity bill. A map is provided giving the solar zones based on the average amount of solar radiation.

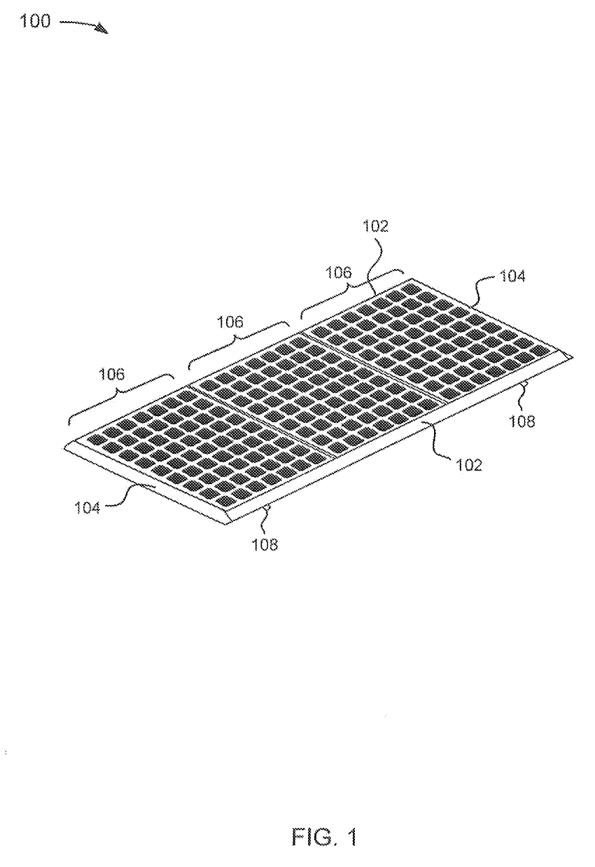

FIG. 1 depicts a diagram 100 of an example of an integral photovoltaic unit, comprising a mounting frame, which includes supports 102 and 104, one or more solar cell assemblies 106 mounted on the mounting frame, and brackets 108 for fixing the integral photovoltaic unit onto an exterior structure.

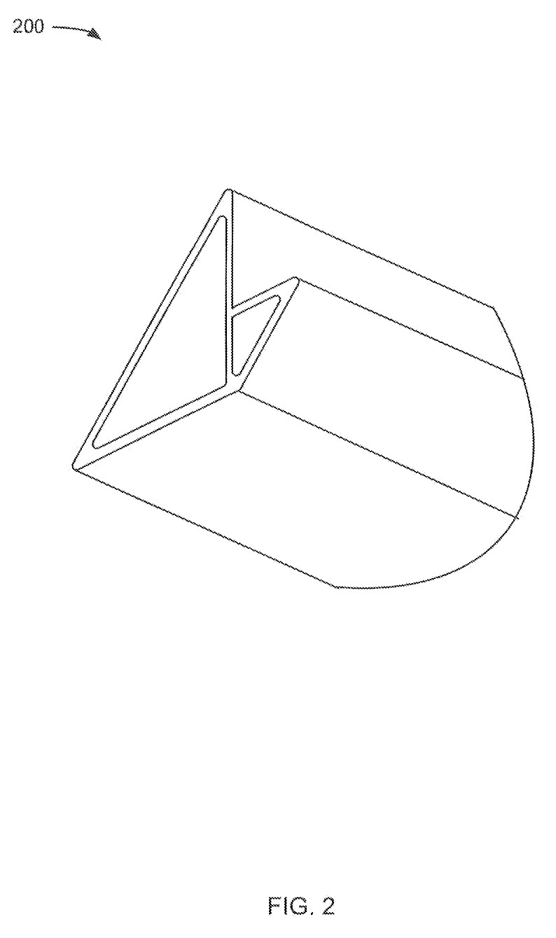

FIG. 2 depicts a triangular shaped rail as used in the mounting frame of an integral photovoltaic unit. The triangular shape of the rail provides greater strength per unit length than straight rails of the same extrusion thickness.

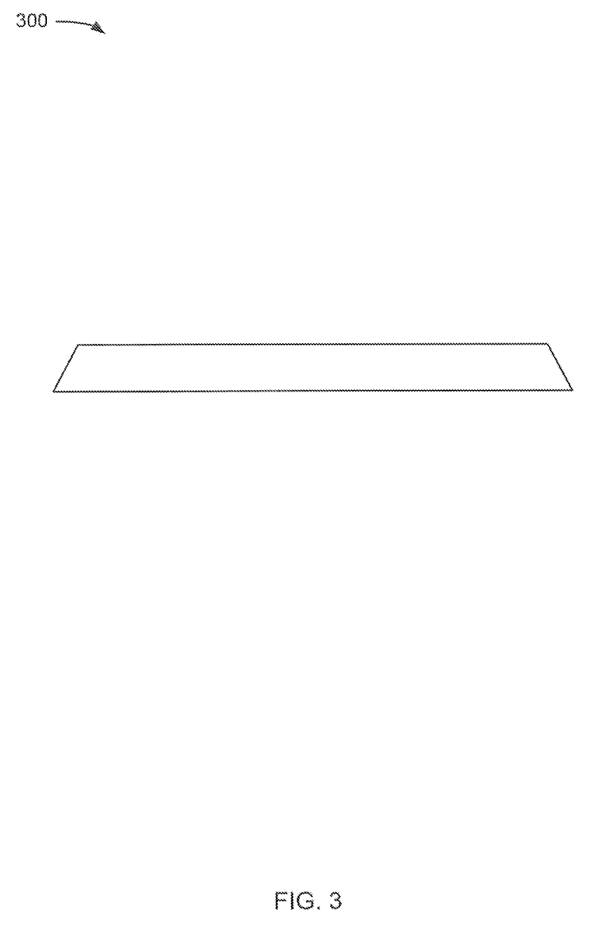

FIG. 3 depicts a flat end cap. Two ends of the flat end cap may each be connected to a triangular shaped rail to form a frame. The flat end cap saves material compared to a beveled rail. The flat end caps provide enough strength, as most of the load from the integral photovoltaic units may be on the triangular shaped rails.

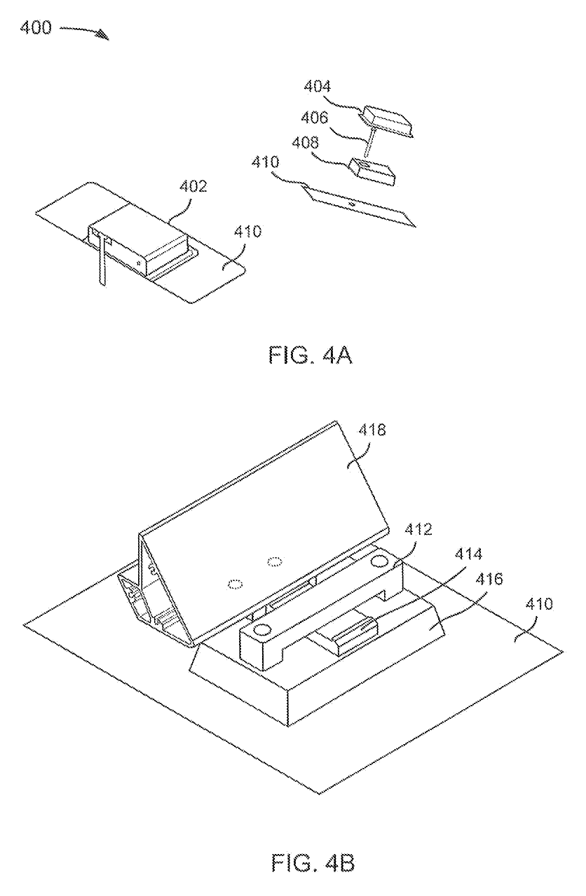

FIG. 4A depicts a mounting block for mounting a photovoltaic unit onto an exterior structure 410. In the example of FIG. 4A, the mounting block 402 includes a lag bolt 406 or other means for attaching the mounting block 402 to an exterior structure 410, and a backing 408. In a further embodiment, the mounting block 402 includes a UV protective film 404. In one embodiment, instead of a UV protective film covering the backing 408 a UV protective paint may be applied to the mounting block.

In one embodiment, a mounting block 402 is installed on an exterior structure 410 and used as an attachment means for mounting a photovoltaic unit onto the exterior structure 410. The mounting block 402 includes a backing 408, which may be comprised of a pre-drilled block that can be attached to the exterior structure 410. In a non-limiting example, the backing 408 may be attached to the exterior structure 410 using a bolt 406. The block provides a large surface onto which the brackets of the photovoltaic unit can be attached, thereby providing a margin of error for installing the photovoltaic unit onto the exterior structure 410. The screws attaching the brackets to the block can be attached anywhere along the surface of the block. These screws may be self-tapping screws. In one embodiment, the brackets may be attached to the mounting block first and then attached to the photovoltaic unit. In a non-limiting example, the backing 408 can be made of aluminum or a composite material such as wood-plastic composite.

In one embodiment, the mounting blocks are attached to roof rafters. The photovoltaic unit can be mounted to roof rafters via the mounting blocks, even is the roof rafters are not evenly spaced.

FIG. 4B depicts a mounting block for mounting a photovoltaic unit onto an exterior structure. In the example of FIG. 4B, the mounting block includes support block 416, attached to exterior structure 410, and attachment bar 412 attached with support block 416. Clip 414 may be used to mount a photovoltaic unit onto exterior structure 410 via the mounting block. Clip 414 may be attached to frame 418 of the photovoltaic unit. Attachment bar 412, provides a gap between it and support block 416, whereby the photovoltaic unit can be clipped into the mounting block. The gap may be larger than the width of clip 414, thereby allowing for a margin of error for installing the photovoltaic unit onto the exterior structure 410.

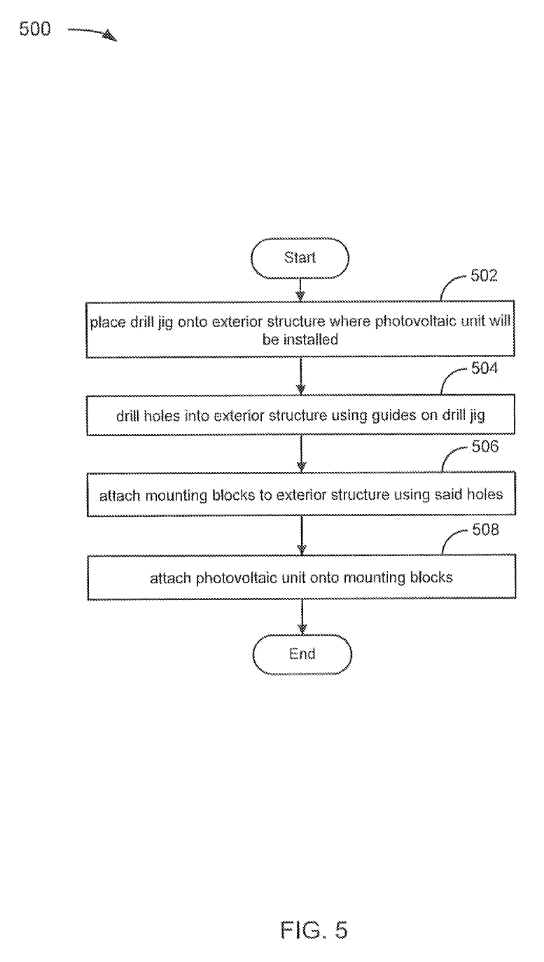

FIG. 5 depicts an example of a flowchart of a method for mounting an integral photovoltaic unit on an exterior structure.

In the example of FIG. 5, the flowchart starts at module 502 with placing the drill jig onto the exterior structure where the photovoltaic unit will be installed. This step may be carried out in a factory environment for a manufactured or modular home prior to the home being delivered to the customer.

In the example of FIG. 5, the flowchart continues to module 504 with drilling holes into the exterior structure using guides on the drill jig. The distance between the holes is roughly the same as the distance between the brackets of the photovoltaic unit to be installed on the roof.

In the example of FIG. 5, the flowchart continues to module 506 with attaching mounting blocks to the exterior structure using the holes. The mounting blocks may be as described with reference to FIG. 4, and may be bolted to the exterior structure through the holes drilled using the drill jig.

In the example of FIG. 5, the flowchart continues to module 508 with attaching the photovoltaic unit onto the mounting blocks. As described with reference to FIG. 4, the mounting blocks provide a large area onto which the brackets of the photovoltaic unit may be attached, thereby allowing for a margin of error for installing the photovoltaic unit onto the exterior structure. Having attached the photovoltaic unit onto the mounting blocks, the flowchart terminates.

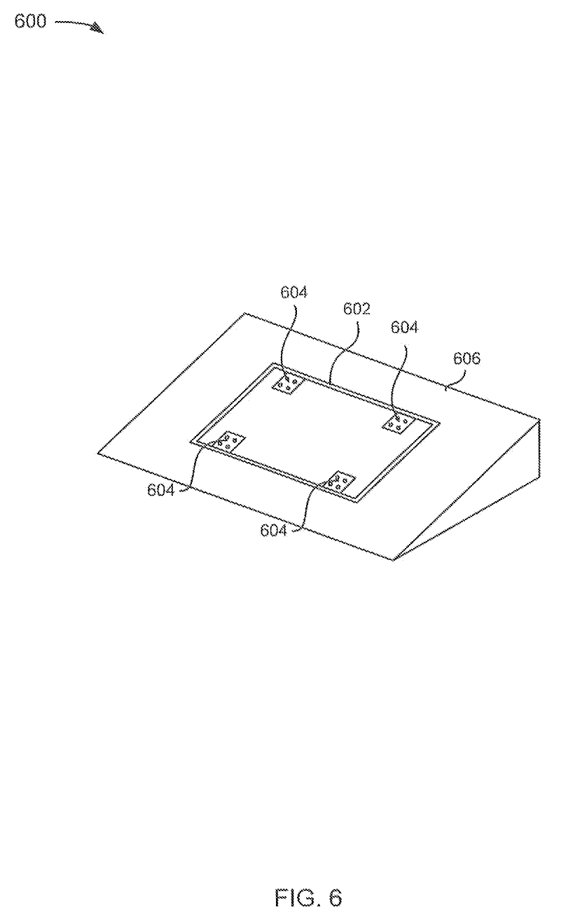

FIG. 6 depicts an example of a drill jig for positioning the means for fixing an integral photovoltaic unit onto an exterior structure 606. FIG. 6 includes a frame 602 to which a multitude of plates 604 are attached. Plates 604 may include slots that may be used as guides to install means for fixing the photovoltaic unit onto the exterior structure 606. In one embodiment, these fixing means may be mounting blocks, which will be described later.

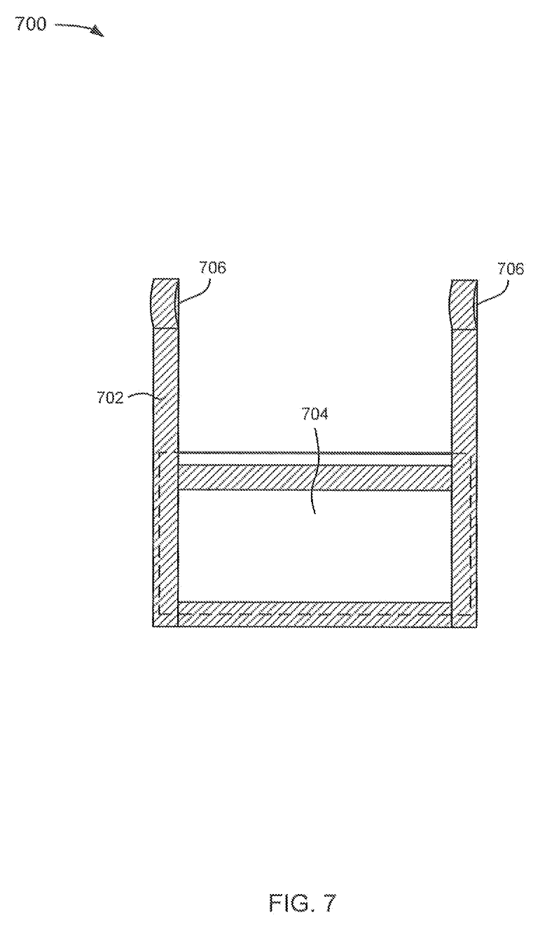

FIG. 7 depicts a sling 702 that may be strapped around the integral photovoltaic unit 704 to pull said photovoltaic unit 704 up to an exterior structure, such as, for example, a roof. In a non-limiting example, the sling 702 may be made of any of the following materials, or a combination thereof: nylon webbing, polyester strapping, or a similar material. The sling 702 may further include ratchet straps or loops 706 that allow for adjustability of the sling 702 around the photovoltaic unit 704. Additionally, the sling 702 may have means for gripping the ends of the sling 702 to pull the photovoltaic unit 704 up to the exterior structure. In one embodiment, one or more ladders may be used to guide the photovoltaic unit 704 when it is pulled up to the exterior structure. The sling 702 may also have an additional rope tied to it, which is attached to a tie-off point for additional safety and leverage.

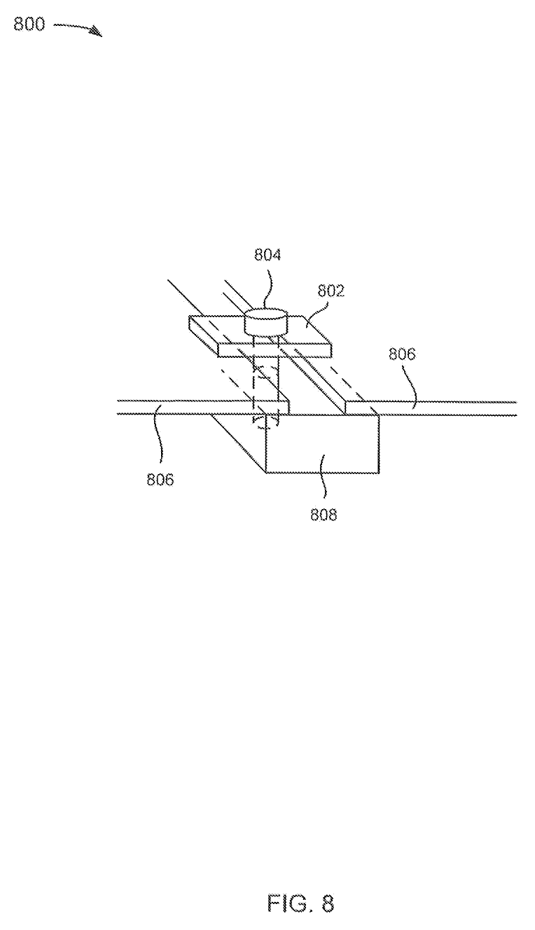

FIG. 8 depicts an example of a clip for securing solar cell assemblies to a mounting frame. Adjacent solar cell assemblies 806 may be fixed onto a mounting frame by one or more clips that are screwed into a cross support 808 of the mounting frame. Bolts 804 may be used to screw down the clips 802, and the bolts 804 may be screwed into holes in the cross support 808, without the need to access the other side of the mounting frame. In the example of FIG. 8, clip 802 is used to secure solar cell assemblies 806 onto a cross support 808 of a mounting frame. The clip 802 is attached to the cross support 808 by a bolt or other attaching means, and clamps down the side of the one or more solar cell assemblies 806 onto the mounting frame.

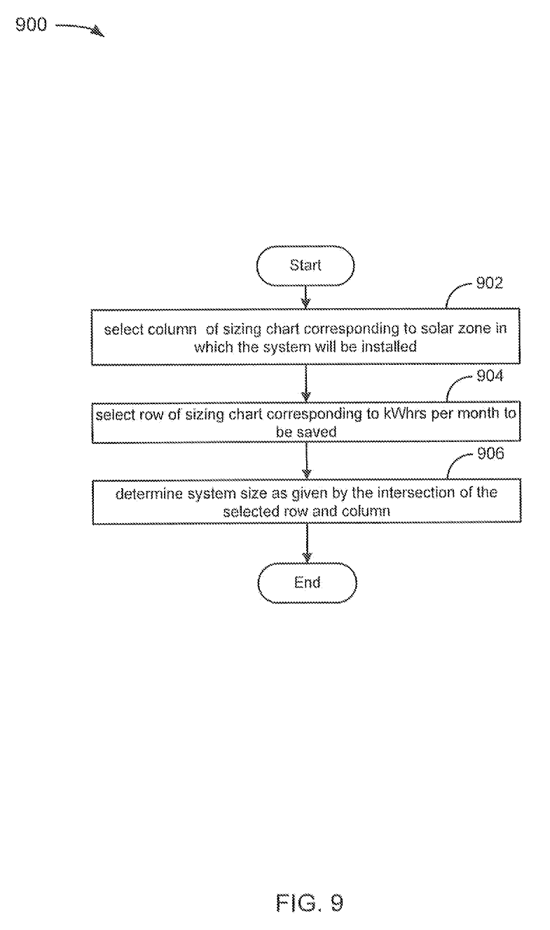

FIG. 9 depicts an example of a flowchart of a method for a customer to select the optimal photovoltaic system size. In the example of FIG. 9, the flowchart starts at module 902 with selecting a column corresponding to the solar zone in which the system will be installed. The flowchart continues to module 904 with selecting a row corresponding to the amount of energy by which the electricity bill is to be reduced by. The flowchart continues to module 906 with connecting the selected row and column to determine the amount of photovoltaic units needed for the system to achieve the desired reduction in energy costs. In another embodiment, the rows and columns may be interchanged.

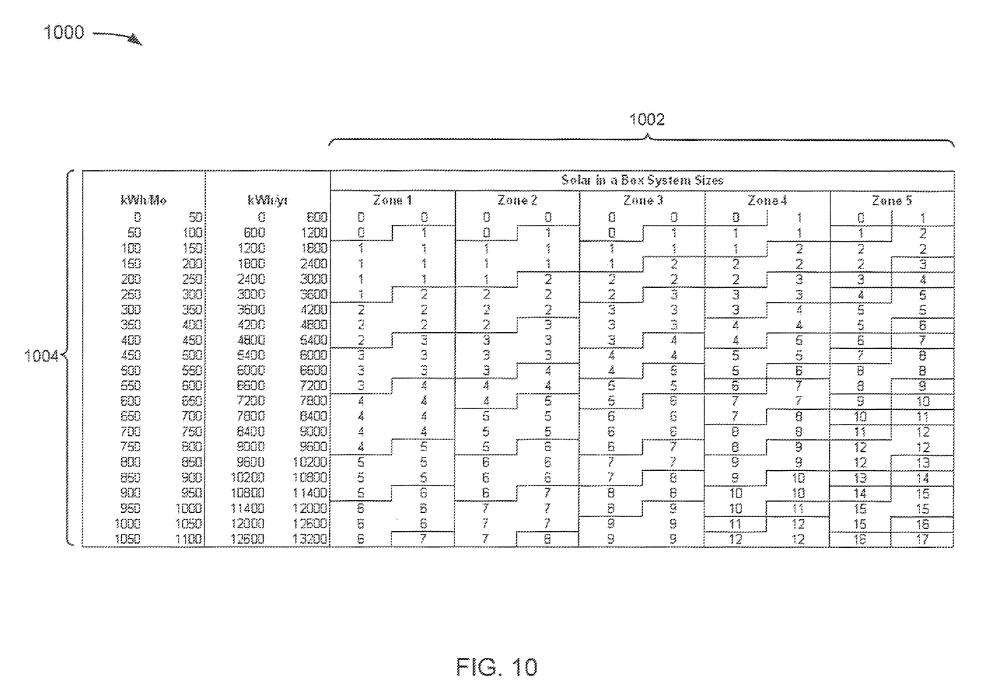

FIG. 10 depicts an example of a sizing chart for selecting the optimal photovoltaic system size as described above. Columns 1002 contain the solar zones. Rows 1004 contain the desired energy production of the system.

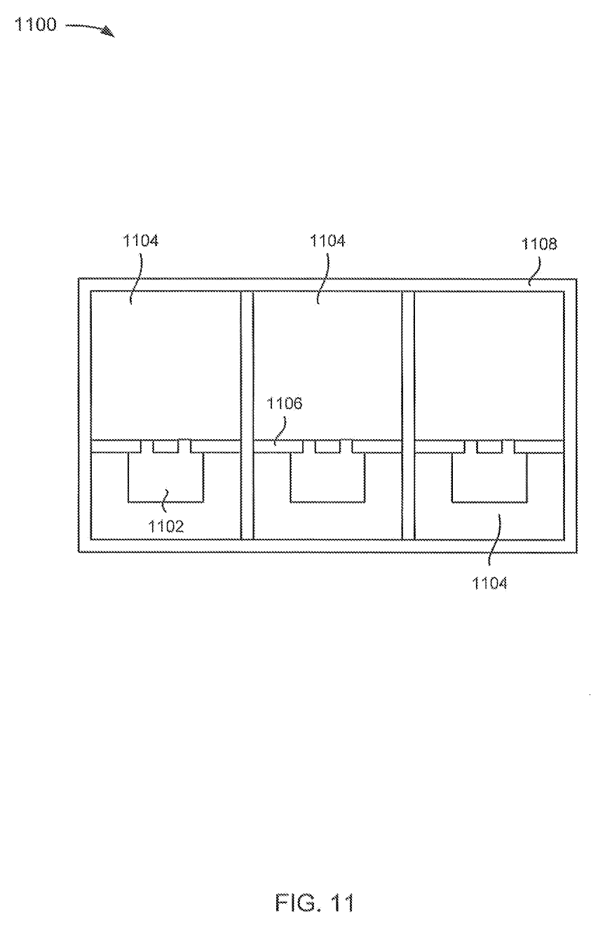

FIG. 11 depicts an example of a micro-inverter connected with the integral photovoltaic unit. In the example of FIG. 11, a micro-inverter 1102 is attached to the back of each solar cell assembly 1104. In a non-limiting example, the micro-inverter is attached to the support 1106 connected to the mounting frame 1108 of the integral photovoltaic unit. The micro-inverters 1102 may be electrically connected to each other and provide electrical connections to micro-inverters on other photovoltaic units and/or to the power grid of the house onto which the units are mounted.

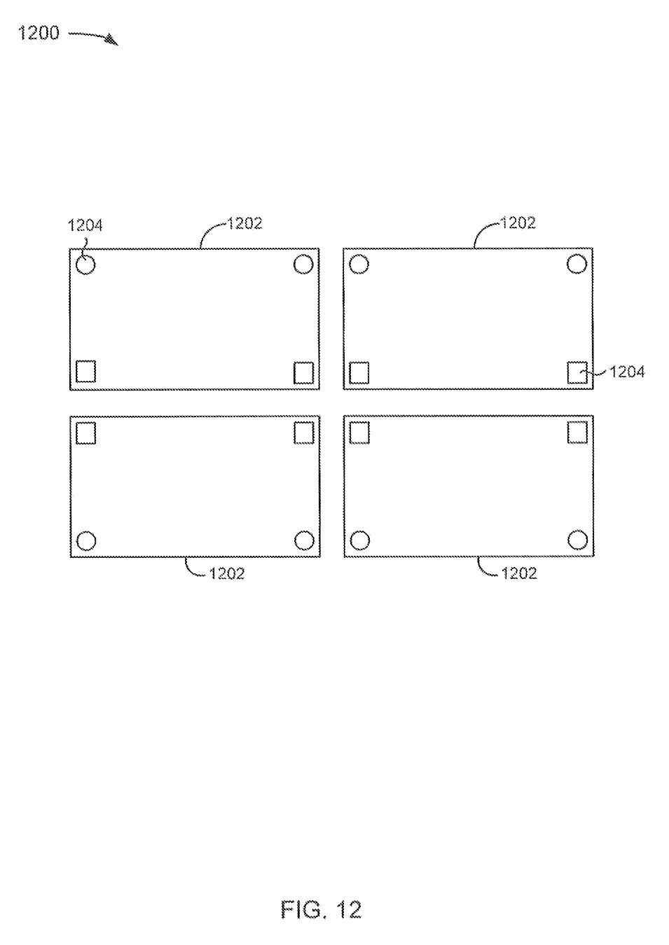

FIG. 12 depicts an example of integral photovoltaic units 1202 marked with color and/or symbol codes 1204 to facilitate installation of an arrangement of the units 1202. In the example of FIG. 12, correct electrical connection of the micro-inverters 1206 may be achieved by aligning adjacent integral photovoltaic units 1202 such that matching colors and/or symbols 1204 on each integral photovoltaic unit 1202 are aligned.

What is claimed is:

1. A pre-assembled integral photovoltaic unit comprising:
a mounting frame;
one or more solar cell assemblies mounted to said mounting frame;
an attachment means on the mounting frame for attaching the unit to an exterior structure; and
one or more electrical leads electrically connecting the plurality of solar cell assemblies;
one or more electronic components electrically connected with said solar cell assemblies.

2. The integral photovoltaic unit of claim 1, wherein at least one of the electronic components is a micro-inverter.

3. The integral photovoltaic unit of claim 2, wherein the micro-inverter is attached to the mounting frame.

4. The integral photovoltaic unit of claim 1, wherein the mounting frame is made of a metallic material.

5. The integral photovoltaic unit of claim 4, wherein the solar cell assemblies are grounded.

6. The integral photovoltaic unit of claim 1, wherein the mounting frame is made of a non-metallic material.

7. The integral photovoltaic unit of claim 1, wherein said non-metallic material is fiber glass or carbon fiber

8. The integral photovoltaic unit of claim 1, wherein the solar cell assemblies are photovoltaic modules.

9. The integral photovoltaic unit of claim 1, wherein the solar cell assemblies are photovoltaic laminates.

10. The integral photovoltaic unit of claim 6, wherein the one or more solar cell assemblies are photovoltaic laminates.

11. The integral photovoltaic unit of claim 1, wherein the exterior structure is a roof.

12. The integral photovoltaic unit of claim 1 further comprising a protective crate, wherein said protective crate fits over the mounting frame to protect said solar cell assemblies during transportation of the integral photovoltaic unit.

13. A mounting frame for holding a plurality of solar cell assemblies, the mounting frame comprising:
two or more triangular shaped rails;
two or more flat end caps; and
a plurality of brackets for attaching said mounting frame to an exterior structure;
wherein said flat end caps are attached to an end of at least two of the two or more triangular shaped rails, wherein at least two of the triangular shaped rails are substantially parallel to each other, whereby said triangular shaped rails and said flat end caps form a frame.

14. The mounting frame of claim 13, wherein said triangular shaped rails and said flat end caps are made of a non-metallic material.

15. The mounting frame of claim 13, wherein the exterior structure is a roof, further wherein the triangular shaped rails are substantially parallel to an eave of the roof.

16. The mounting frame of claim 13 further comprising one or more cross supports.

17. The mounting frame of claim 16, wherein one or more clips are disposed between adjacent solar cell assemblies and are attached to said cross supports, whereby the solar cell assemblies are held in place by said one or more clips, wherein the clips are configured to be attached with the cross supports without having to access the other side of the mounting frame.

18. A method for installing an integral photovoltaic unit on an exterior structure, the method comprising:
placing a drill jig on the exterior structure to prepare one or more locations where said integral photovoltaic unit will be attached to the exterior structure;
attaching one or more mounting blocks to said one or more locations, wherein said mounting blocks have a large area onto which said integral photovoltaic unit can be fixed; and
installing said integral photovoltaic unit onto the exterior structure.

19. The method of claim 18, wherein said exterior structure is a roof.

20. The method of claim 19, wherein the integral photovoltaic unit is installed on the roof of a pre-fabricated house, prior to said pre-fabricated house being transported to a destination site.

21. The method of claim 15, wherein the integral photovoltaic is covered with a protective crate.

22. The method of claim 21, wherein the protective crate is made of wood, plastic, or cardboard, or any combination thereof.

23. The method of claim 18 further comprising:
strapping a sling around said photovoltaic unit;
adjusting said sling to fit the photovoltaic unit;
pulling said sling, including said photovoltaic unit, up to said exterior structure.

24. The method of claim 23, wherein said sling has means for gripping one or more pulling ends of said sling.

25. The method of claim 23, wherein said sling is made of nylon webbing.

26. The method of claim 23 further comprising one or more guides for pulling said photovoltaic unit up to said exterior structure along said one or more guides.

27. The method of claim 26, wherein said one or more guides are ladders.

28. A portable template for use in conjunction with a mounting tool to install one or more photovoltaic units onto an exterior structure, the portable template comprising:
a rigid frame; and
a plurality of guides attached to said rigid frame, wherein said guides are used to guide a tool to enable a plurality of fixings to be attached to the exterior structure.

29. A method for facilitating installation of an arrangement of integral photovoltaic units, the method comprising:
providing at least two integral photovoltaic units, wherein each of the at least two integral photovoltaic units includes at least one micro-inverter, further wherein the integral photovoltaic units include visual codes indicating the required orientation of the integral photovoltaic units to enable correct electrical connection of the micro-inverters.

30. An integral photovoltaic unit comprising:
a mounting frame;
one or more photovoltaic modules connected with said mounting frame;
at least one micro-inverter electrically connected with the photovoltaic modules;
wherein the photovoltaic modules are grounded;
wherein the integral photovoltaic unit includes visual codes indicating the orientation of the integral photovoltaic unit to enable correct electrical connection of the integral photovoltaic unit with an adjacent photovoltaic unit.

31. A method for selecting a photovoltaic system size using a sizing chart, the method comprising:
selecting a column/row corresponding to a solar zone where the photovoltaic system will be installed;
selecting a row/column corresponding to a desired reduction in energy costs;
connecting the selected column/row and row/column to determine the photovoltaic system size needed to achieve the desired reduction in energy costs.
